(19) United States
(12) Patent Application Publication
(10) Pub. No.: US 2021/0202853 A1
(43) Pub. Date: Jul. 1, 2021

(54) DISPLAY APPARATUS

(71) Applicant: LG Display Co., Ltd., Seoul (KR)

(72) Inventors: HyunJin AN, Paju-si (KR); SeungHan PAEK, Paju-si (KR); Seongwoo PARK, Paju-si (KR); Kyungjae YOON, Paju-si (KR)

(73) Assignee: LG Display Co., Ltd., Seoul (KR)

(21) Appl. No.: 17/130,932

(22) Filed: Dec. 22, 2020

(30) Foreign Application Priority Data
Dec. 31, 2019 (KR) 10-2019-0180111

(51) Int. Cl. H01L 51/00

(52) U.S. Cl. CPC H01L 51/0011; H01L 51/0097

(57) ABSTRACT

A display apparatus includes a display area, a non-display area surrounding the display area, and a bending area formed in at least one side of the non-display area. The display apparatus includes a first glass substrate including a first flat surface and a first rear surface opposite to the first flat surface, the first flat surface being overlapped with the display area, a second glass substrate including a second flat surface and a second rear surface opposite to the second flat surface, the second flat surface being overlapped with the non-display area adjacent to the bending area, a first mask member provided on the first rear surface, and a second mask member provided on the second rear surface.

### CROSS-REFERENCE TO RELATED APPLICATIONS

This application claims the benefit of the Korean Patent Application No. 10-2019-0180111 filed on Dec. 31, 2019 which is hereby incorporated by reference as if fully set forth herein.

### BACKGROUND

### Technical Field

The present disclosure relates to a display apparatus.

### Discussion of the Related Art

Generally, a display apparatus is widely used as a display screen of various electronic devices such as a mobile communication terminal, an electronic diary, an electronic book, a portable multimedia player (PMP), a navigator, an Ultra Mobile PC (UMPC), a mobile phone, a smart phone, a tablet personal computer (PC), a watch phone, an electronic pad, a wearable device, a watch phone, a portable information device, a vehicle control display device, a television, a notebook computer, and a monitor.

Recently, studies and development of a display apparatus that may embody a maximum screen by reducing a bezel area where an image is not displayed in a size of the same display panel are ongoing.

For bezel bending, a laser lift off process is applied to a display apparatus to which a conventional glass substrate is applied, whereby problems occur in that a defect caused by the laser lift off process may occur and a manufacturing cost is increased.

Also, in the display apparatus to which a conventional glass substrate is applied, a rear surface of the glass substrate is exposed as it is, whereby a problem occurs in that a defect caused by a damage is generated.

### SUMMARY

The inventors of the present disclosure have continuously studied and developed technologies that can replace a laser release process, and have invented a display apparatus of a new structure, which may be manufactured without the laser release process.

Accordingly, embodiments of the present disclosure are directed to a display apparatus that substantially obviates one or more of the problems due to limitations and disadvantages of the related art.

An aspect of the present disclosure is to provide a display apparatus that may be manufactured without a laser release process for detaching a mother glass substrate from a flexible substrate.

Another aspect of the present disclosure is to provide a display apparatus in which reliability is improved and a width of a bezel area may be minimized.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a display area, a non-display area surrounding the display area, and a bending area formed in at least one side of the non-display area, wherein the display apparatus comprises a first glass substrate including a first flat surface and a first rear surface opposite to the first flat surface, the first flat surface being overlapped with the display area, a second glass substrate including a second flat surface and a second rear surface opposite to the second flat surface, the second flat surface being overlapped with the non-display area adjacent to the bending area, a first mask member provided on the first rear surface, and a second mask member provided on the second rear surface.

The present disclosure may provide a display apparatus that may be manufactured without a laser release process of a glass substrate. Also, the present disclosure may provide a display apparatus in which reliability is improved and a width of a bezel area may be minimized.

Also, since the display apparatus of the present disclosure comprises a mask member arranged on a rear surface of the glass substrate, scattering and damage caused by etching of the glass substrate may be prevented from occurring. Moreover, since the display apparatus of the present disclosure comprises a member having an excellent heat emission characteristic, its heat dispersion and heat emission effect may be improved.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a perspective view illustrating a display apparatus according to one embodiment of the present disclosure;

FIG. 2 is a cross-sectional view taken along line I-I′ of FIG. 1;

FIG. 3 is a perspective view illustrating a display apparatus according to one embodiment of the present disclosure;

FIG. 4 is a cross-sectional view taken along line II-IF of FIG. 3;

FIGS. 5A to 5G illustrate a manufacturing method of a display apparatus according to one embodiment of the present disclosure;

FIGS. 6A to 6C are another example of a sectional view taken along line II-II′ of FIG. 3;

FIGS. 7A to 7D are other example of a sectional view taken along line II-IF of FIG. 3;

FIG. 8 is a perspective view illustrating a display apparatus according to one embodiment of the present disclosure;

FIG. 9 is a cross-sectional view taken along line of FIG. 8;

FIG. 10 is a perspective view illustrating a display apparatus according to one embodiment of the present disclosure;

FIG. 11 is a cross-sectional view taken along line IV-IV′ of FIG. 10;

FIG. 12 is a perspective view illustrating a display apparatus according to one embodiment of the present disclosure;

FIG. 13 is a cross-sectional view taken along line V-V′ of FIG. 12;

FIG. 14 is a perspective view illustrating a display apparatus according to one embodiment of the present disclosure;

FIG. 15 is a cross-sectional view taken along line VI-VI′ of FIG. 13;

FIG. 16 is a perspective view illustrating a display apparatus according to one embodiment of the present disclosure;

FIG. 17 is a cross-sectional view taken along line VII-VII′ of FIG. 16;

FIG. 18 is a perspective view illustrating a display apparatus according to one embodiment of the present disclosure;

FIG. 19 is a cross-sectional view taken along line VIII-VIII′ of FIG. 18;

FIG. 20 is a perspective view illustrating a display apparatus according to one embodiment of the present disclosure;

FIG. 21 is a cross-sectional view taken along line IX-IX′ of FIG. 20;

FIG. 22 is a perspective view illustrating a display apparatus according to one embodiment of the present disclosure;

FIG. 23 is a cross-sectional view taken along line X-X′ of FIG. 22.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’, and ‘next to˜’, one or more portions may be arranged between two other portions unless ‘just’ or ‘direct’ is used.

In describing a time relationship, for example, when the temporal order is described as ‘after˜’, ‘subsequent˜’, ‘next˜’, and ‘before˜’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, a display apparatus according to the present disclosure will be described in detail with reference to the accompanying drawings. Wherever possible, the same reference numbers will be used throughout the drawings to refer to the same or like parts. Since a scale of each of elements shown in the accompanying drawings is different from an actual scale for convenience of description, the present disclosure is not limited to the shown scale.

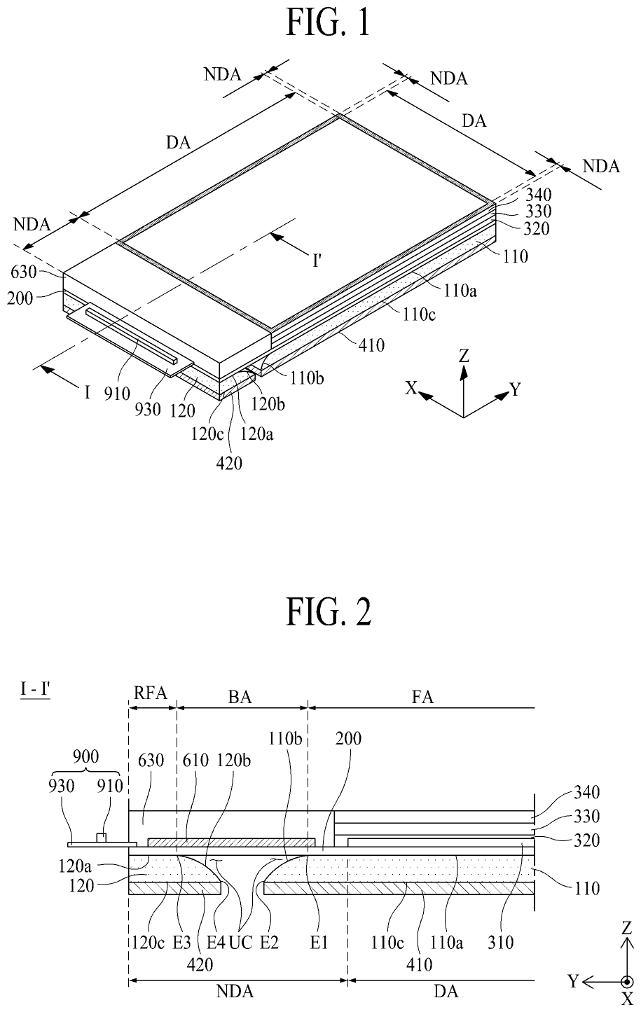

FIG. 1 is a perspective view illustrating a display apparatus according to one embodiment of the present disclosure, and FIG. 2 is a cross-sectional view taken along line I-I′ of FIG. 1.

Referring to FIGS. 1 and 2, the display apparatus according to one embodiment of the present disclosure comprises a display area DA, a non-display area NDA surrounding the display area, and a bending area BA overlapped with at least a portion of the non-display area NDA, and comprises a first glass substrate 110, a second glass substrate 120, a flexible substrate 200, a first mask member 410, and a second mask member 420.

The display area DA is an area where an image is displayed, and may include a plurality of pixels. The display area DA may be supported by a first flat surface 110a of a first glass substrate 110. The plurality of pixels may be arranged in the form of matrix, and each of the pixels may include subpixels. The display area DA may substantially have a rectangular shape. However, embodiments of the present disclosure are not limited to the rectangular shape, and the display area DA may have a random polygonal shape. For example, the display area DA may have a triangle, a pentagonal shape and a hexagonal shape in accordance with a shape of the display apparatus. In the present disclosure, for convenience of description, the display area DA having a rectangular shape based on the display apparatus of a rectangular shape will be described.

The non-display area NDA is an area surrounding the display area DA, and elements and circuit lines for driving the display area DA may be arranged in the non-display area NDA.

The bending area BA may be defined as an area provided such that the display apparatus is partially bent. Therefore, the display apparatus according to one embodiment of the present disclosure may be bent to have a certain curvature radius in accordance with bending of the bending area BA.

Also, in the display apparatus according to one embodiment of the present disclosure, a flat area FA, a bending area BA, and a rear flat area RFA may be defined. In this case, since the bending area BA is the same as the aforementioned bending area, its description will be omitted.

The flat area FA may be defined as an area overlapped with the first flat surface 110a of the first glass substrate 110. Also, the flat area FA may be an area that includes a predetermined non-display area NDA overlapped with the display area DA, surrounding the display area DA.

The rear flat area RFA may be defined as an area which is overlapped with a second flat surface 120a of a second glass substrate 120 and not overlapped with the bending area BA. The rear flat area RFA may be provided with a panel driving circuit 900.

The first glass substrate 110 may include a first etching surface 110b provided to overlap the bending area BA. In this case, the case that the first etching surface 110b is overlapped with the bending area BA may mean that the first etching surface 110b is headed for a rear surface of the flexible substrate 200 overlapped with the bending area BA. Also, if the bending area BA of the display apparatus is not provided with the first etching surface 110b, since the display apparatus cannot be bent, the bending area BA of the display apparatus may be defined to overlap the first etching surface 110b.

Also, the first glass substrate 110 may include a first flat surface 110a and a first etching surface 110b arranged at one side of the first flat surface 110a, and may further include a first rear surface 110c opposite to the first flat surface 110a.

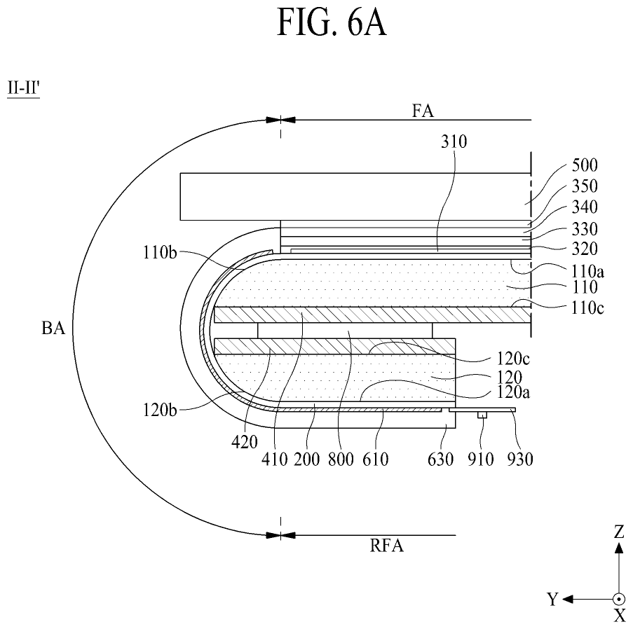

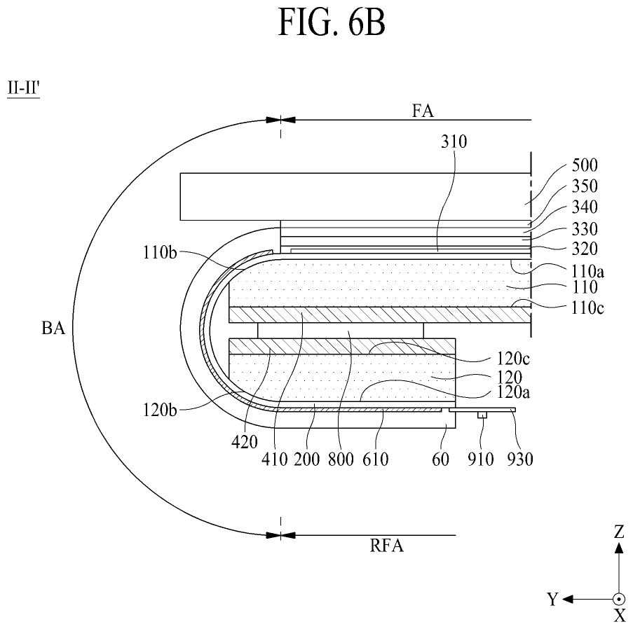

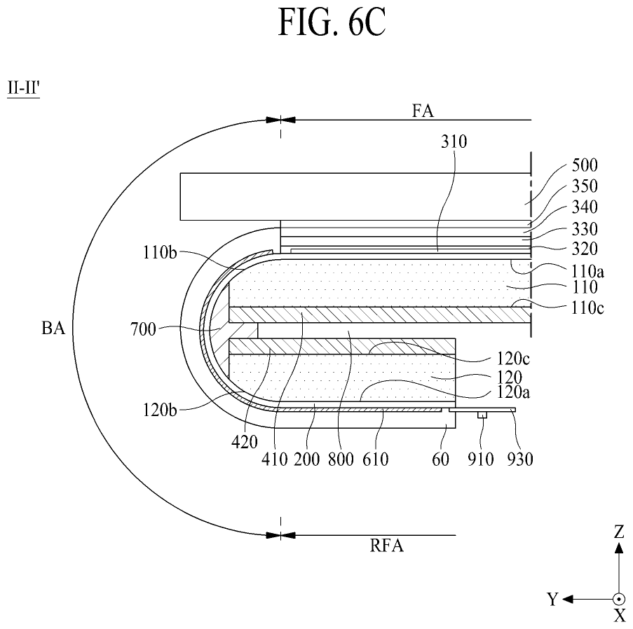

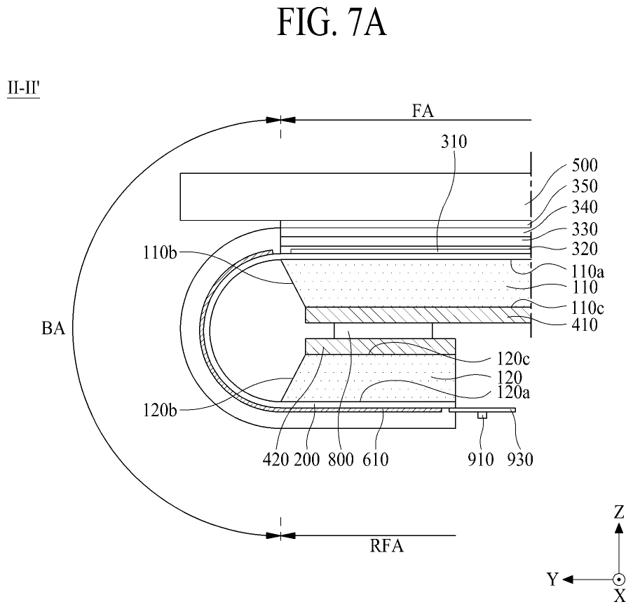

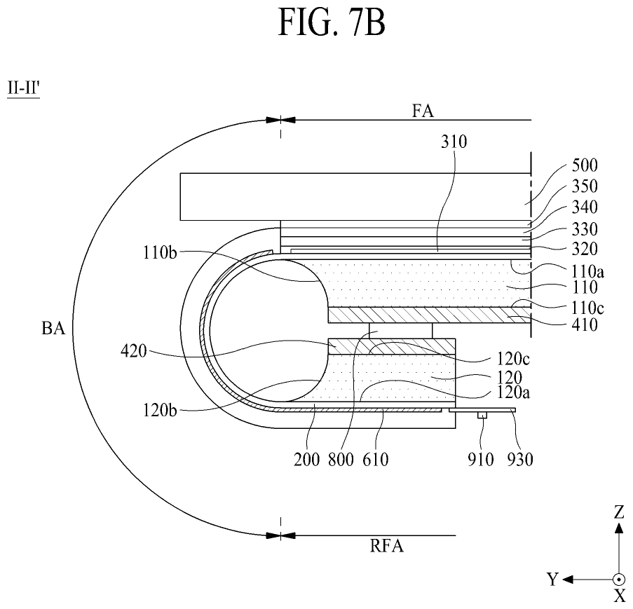

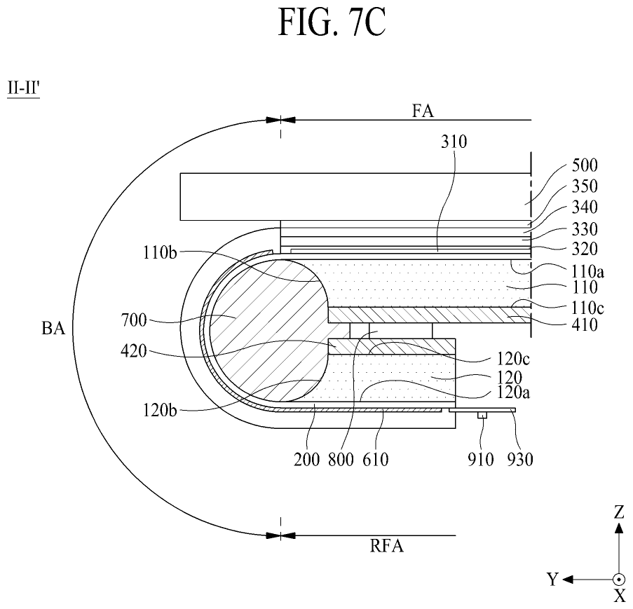

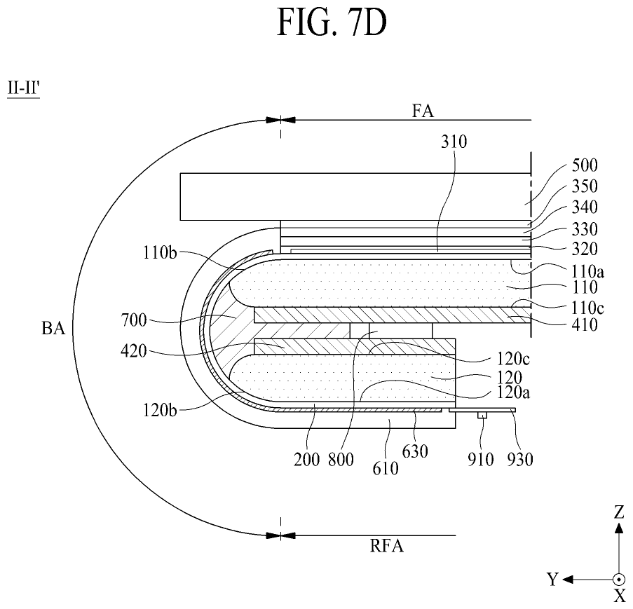

Also, the first glass substrate 110 may be defined by a first end E1 which is a boundary between the first flat surface 110a and the first etching surface 110b and a second end E2 which is a boundary between the first etching surface 110b and the first rear surface 110c. An inclination of the first etching surface 110b may be defined by an inclined surface connecting the first end E1 with the second end E2. Referring to FIGS. 1 and 2, although the first etching surface 110b is shown to have a convex curved surface, the embodiment of the present disclosure is not limited to this example. Various shapes of the first etching surface 110b will be described later with reference to FIGS. 6A to 6C and 7A to 7D.

The second glass substrate 120 may include a second etching surface 120b provided to overlap the bending area BA. In this case, the case that the second etching surface 120b is overlapped with the bending area BA may mean that the second etching surface 120b is headed for the rear surface of the flexible substrate 200 overlapped with the bending area BA. Also, if the bending area BA of the display apparatus is not provided with the second etching surface 120b, since the display apparatus cannot be bent, the bending area BA of the display apparatus may be defined to overlap the second etching surface 120b.

Also, the second glass substrate 120 may include a second flat surface 120a and a second etching surface 120b arranged at one side of the second flat surface 120a, and may further include a second rear surface 120c opposite to the second flat surface 120a.

The first glass substrate 110 and the second glass substrate 120 may include a glass material. The first glass substrate 110 and the second glass substrate 120 according to one example may have a thickness of 0.01 mm to 1.0 mm to maintain flatness of the first flat surface 110a and the second flat surface 120a or shield water or oxygen from being permeated into the display apparatus. However, the thickness of the first glass substrate 110 and the second glass substrate 120 is not limited to the above example, and may be changed depending on a design condition of the display apparatus.

Also, if the first etching surface 110b of the first glass substrate 110 and the second etching surface 120b of the second glass substrate 120 are formed as shown in FIG. 2, the etching surfaces may be considered to have an undercut UC structure or an inverse tapered shape. In this case, the undercut UC may mean that the first end E1 and a third end E3 are formed to be wider than an opening pattern for etching when it is assumed that the second end E2 and a fourth end E4 correspond to the opening pattern. A detailed structure of the first etching surface 110b of the first glass substrate 110 and the second etching surface 120b of the second glass substrate 120 will be described later with reference to FIGS. 6A to 6C and 7A to 7D.

As the first etching surface 110b and the second etching surface 120b according to one embodiment of the present disclosure are formed by a glass etching process at the same time, these etching surfaces may have the same shape within an etching process error range. For example, if the first etching surface 110b and the second etching surface 120b are formed in a streamlined shape, these etching surfaces may have the same circular curvature or oval curvature. If the first etching surface 110b and the second etching surface 120b are formed in an oblique shape, these etching surfaces may have the same inclination. If the first etching surface 110b and the second etching surface 120b are formed in a stair shape, these etching surfaces may be formed in a stair shape having the same step difference.

According to one example, the first glass substrate 110 and the second glass substrate 120 may include, but not limited to, a soda-lime glass or a non-alkali glass. The first glass substrate 110 and the second glass substrate 120 may include glass widely used to manufacture a flat display panel. Moreover, the first glass substrate 110 and the second glass substrate 120 may include any one or a deposited structure of sapphire glass and gorilla glass.

The first glass substrate 110 according to one example may have a thickness of 0.01 mm to 1 mm to maintain flatness of the display apparatus or shield water or oxygen from being permeated into the display apparatus, but its thickness may be changed depending on a size of the display apparatus without being limited to this example. The first glass substrate 110 according to another example may have a thickness of 0.01 mm to 0.5 mm to be bent together with the display apparatus while shielding water or oxygen from being permeated into a display area, but its thickness may be changed depending on a size of the display apparatus without being limited to this example.

The flexible substrate 200 may be overlapped with the bending area BA, and may be formed to overlap the first etching surface 110b of the first glass substrate 110 and the second etching surface 120b of the second glass substrate 120. Also, as shown in FIGS. 1 and 2, the flexible substrate 200 may be provided on the first flat surface 110a and the second flat surface 120a.

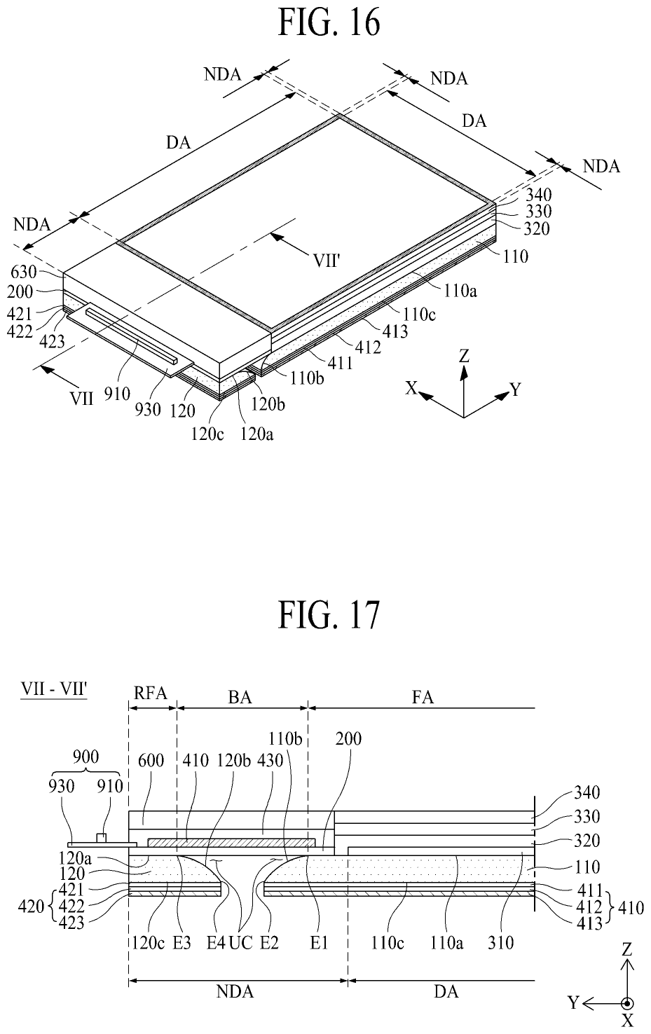

Although the flexible substrate 200 is overlapped with the display area DA and the non-display area NDA in FIGS. 1 to 4, the scope of the present disclosure is not limited to FIGS. 1 to 4. The flexible substrate 200 may be formed to overlap the bending area BA of the non-display area NDA without overlapping the display area DA, as described later in FIGS. 16 to 23.

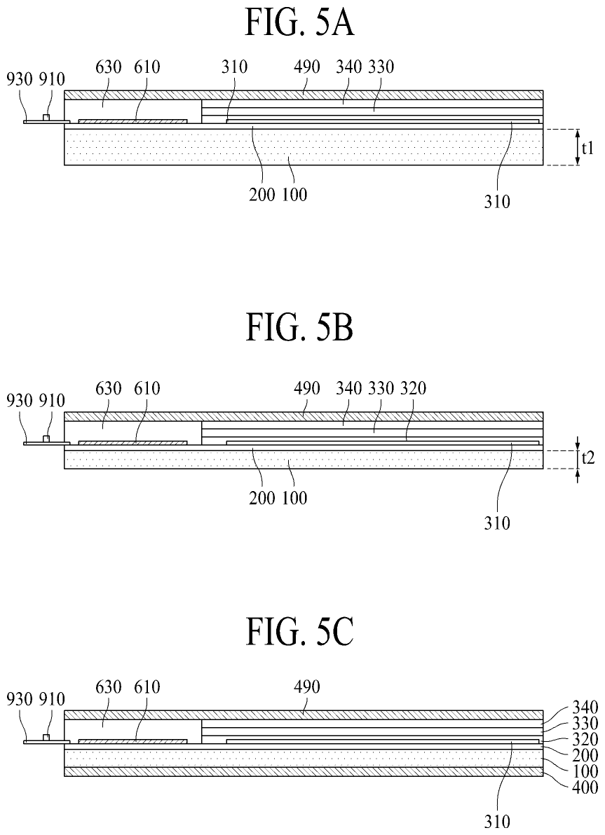

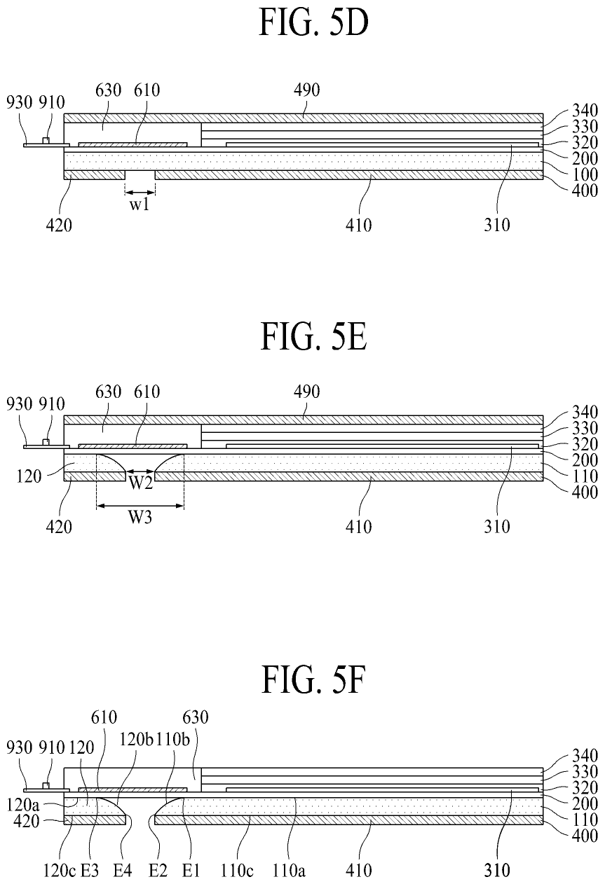

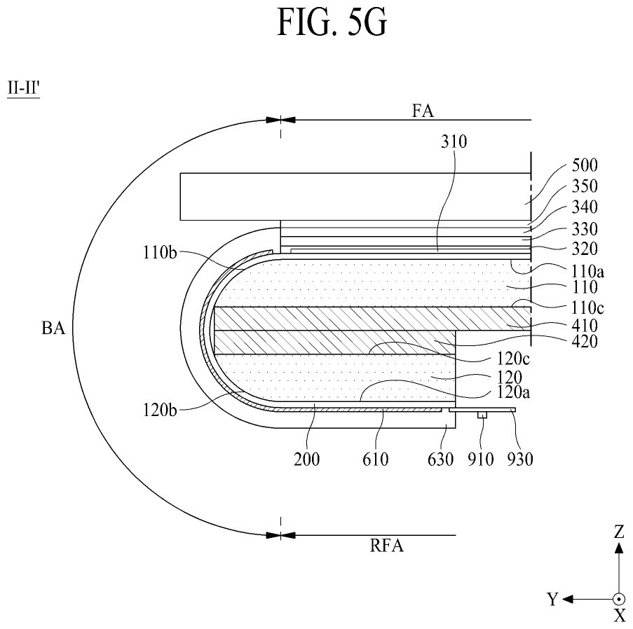

The flexible substrate 200 may be formed of a material having excellent resistance to an etching solution for glass etching described in FIGS. 5A to 5G while including a plastic material having flexibility. In this case, as the etching solution for etching the glass substrates 110 and 120, hydrofluoric acid HF or nitric acid HNO₃ may be used, or an etching solution which is known may be used.

The flexible substrate 200 may include any one of polyimide, photo acryl, polyurethane and silicone based organic matter, for example. More preferably, the flexible substrate 200 may include opaque or colored PI (polyimide). The flexible substrate 200 may be formed in an area overlapped with the first etching surface 110b of the first glass substrate 110, the second etching surface 120b and the second flat surface 120a of the second glass substrate 120 at a certain thickness and then hardened by a hardening process.

In the display apparatus according to one embodiment of the present disclosure, the flexible substrate 200 may be arranged to overlap the first flat surface 110a of the first glass substrate 110 of the display area DA. The display apparatus according to one embodiment of the present disclosure may further comprise a pixel array layer 310, an overcoat layer 320, a touch sensor layer 330 and a functional film 340, which are sequentially formed on the flexible substrate 200 overlapped with the first flat surface 110a. The pixel array layer 310 includes a plurality of pixels provided in a pixel area defined by pixel driving lines provided on the display area DA, displaying an image in accordance with a signal supplied to the pixel driving lines. In this case, the pixel driving lines may include data lines, gate lines and pixel driving power sources. Each of the pixels may include a pixel circuit layer, an anode electrode layer, a self-light emitting diode layer, and a cathode electrode layer.

The pixel circuit layer is provided in a transistor area of each pixel area and driven in accordance with a signal supplied from adjacent pixel driving lines to control light emission of the self-light emitting diode layer. The pixel circuit layer according to one example may include at least two thin film transistors that include a driving thin film transistor provided in the transistor area of each pixel area defined on the first glass substrate 110 and at least one capacitor. In this case, the pixel circuit layer may include at least one TFT of an amorphous silicon thin film transistor (a-Si TFT), a polysilicon thin film transistor (poly-Si TFT), an oxide TFT, and an organic TFT. The anode electrode layer may electrically be connected with the driving thin film transistor.

The self-light emitting diode layer is formed on the anode electrode layer provided in an opening area of each pixel. In this case, the opening area of each pixel area may be defined by a bank pattern formed on the overcoat layer to cover edges of the anode electrode layer.

The self-light emitting diode layer according to one example may include an organic light emitting diode, a quantum dot light emitting diode, or an inorganic light emitting diode. For example, the self-light emitting diode layer may be formed in a deposited structure of a hole injecting layer, a hole transporting layer, an organic light emitting layer, an electron transporting layer, and an electrode injecting layer, which are sequentially deposited. In this case, one or two or more layers of the hole injecting layer, the hole transporting layer, the electron transporting layer and the electron injecting layer may be omitted. The organic light emitting layer may be formed to emit light of the same color per pixel, for example, white light, or may be formed to emit light of different colors per pixel, for example, red light, green light, or blue light.

The cathode electrode layer is formed on the first glass substrate 110 to be commonly connected to the self-light emitting diode layer provided in each pixel area.

Also, the pixel array layer 310 may further include a pad portion and a gate driving circuit.

The pad portion may include a plurality of pad electrodes provided at an edge of at least one side of the first glass substrate 110. Each of the plurality of pad electrodes is electrically connected with the pixel driving lines provided in the pixel array layer 310 through each of a plurality of link lines, and is electrically connected with the gate driving circuit. The pad portion is electrically connected with the panel driving circuit 900 and supplies the signal supplied from the panel driving circuit 900 to the pixel driving lines and the gate driving circuit provided in the pixel array layer 310 through a link line portion 610.

The gate driving circuit may be provided at left and/or right edges of the first glass substrate 110 to be connected with one end and/or the other end of each of the plurality of gate lines. The gate driving circuit generates a gate signal in response to a gate control signal supplied through the pad portion and supplies the generated gate signal to each of the plurality of gate lines. The gate driving circuit may be, but not limited to, a gate built-in circuit formed together with the manufacturing process of the thin film transistor of each pixel.

The overcoat layer 320 is formed on the first glass substrate 110 to surround the pixel array layer 310. The overcoat layer 320 may be formed to protect the pixel array layer 310 from external impact, and may serve to prevent oxygen and/or water and particles from being permeated into the pixel array layer 310. The overcoat layer 320 may be referred to as an encapsulation layer.

The overcoat layer 320 according to one example may include at least one inorganic film. The overcoat layer 320 may further include at least one organic film. For example, the overcoat layer 320 may include a first inorganic encapsulation layer, an organic encapsulation layer and a second inorganic encapsulation layer. The first and second inorganic encapsulation layers may include at least one inorganic material of silicon oxide SiOx, silicon nitride SiNx, silicon oxynitride SiON, titianium oxide TiOx and aluminium oxide AlOx. The organic encapsulation layer may be made of any one of organic material of acryl resin, epoxy resin, phenolic resin, polyamide resin, polyimide resin, and benzocyclobutene resin. The organic encapsulation layer may be expressed as a particle cover layer.

The touch sensor layer 330 may be provided on an upper surface of the overcoat layer 320. The touch sensor layer includes a mutual capacitance type or self-capacitance type touch sensor or touch electrode having a change of capacitance generated in accordance with a user's touch.

The functional film 340 is provided on the touch sensor layer 330 and improves optical characteristics of the display apparatus by polarizing light emitted from each pixel of the pixel array layer 310 or preventing external light from being reflected. For example, the functional film 340 improves visibility and a contrast ratio of the display apparatus by changing external light reflected by a thin film transistor and/or lines provided in each pixel to a circular polarizing state. For example, the functional film 340 according to one example may include a circular polarizer. Optionally, a polarizing layer may be formed in a film type that includes a circular polarizer and attached onto the touch sensor layer by an adhesive.

As shown in FIG. 2, the first etching surface 110b of the first glass substrate 110 may be defined by the first end E1 of the first flat surface of the first glass substrate 110 and the second end E2 of the first rear surface, and the second etching surface 120b of the second glass substrate 120 may be defined by the third end E3 of the second flat surface of the second glass substrate 120 and the fourth end E4 of the second rear surface. The first glass substrate 110 may include the first flat surface 110a, and the first etching surface 110b arranged at one side of the first flat surface 110a, and may further include the first rear surface 110c opposite to the first flat surface 110a.

A micro coating layer 630 may serve to protect a line by forming a resin in a bending position at a thin thickness because a crack may occur due to a tensile force acting on the link line portion 610 arranged on the flexible substrate 200 during bending. The micro coating layer 630 may be made of an acryl based material such as acrylate polymer.

The micro coating layer 630 may control a neutral plane of the bending area BA. The neutral plane may mean a virtual plane to which a stress is not applied as a compressive force and a tensile force applied to a structure are counterbalanced when the structure is bent. If two or more structures are deposited, a virtual neutral plane may be formed between the structures. If the structures are bent in one direction, the structures arranged in a bending direction based on the neutral plane are compressed by bending, whereby a compressive force is applied to the structures. On the contrary, the structures arranged in an opposite direction of the bending direction based on the neutral plane are stretched by bending, whereby a tensile force is applied to the structures. Since the structures are more vulnerable to the tensile force than the compressive force, it is likely that a crack may occur when the tensile force is applied to the structures.

Since the flexible substrate 200 arranged at a lower portion based on the neutral plane is compressed, the compressive force may be applied to the flexible substrate 200, and the tensile force may be applied to the link line portion 610 arranged at an upper portion, whereby a crack may occur due to the tensile force. Therefore, the link line portion 610 may be arranged over the neutral plane to minimize the tensile force applied to the link line portion 610.

The micro coating layer 630 may be arranged on the bending area BA to ascend the neutral plane in an up direction, and the neutral plane may be formed at the same positon as the line or the line may be arranged to be lower than the neutral plane, whereby a stress may not be applied or a compressive force may be applied during bending to reduce occurrence of a crack.

The link line portion 610 may be arranged on the flexible substrate 200 between a display pad portion and the pixel array layer 310. The link line portion according to one example may include a plurality of data link lines connected with a plurality of data pad electrodes arranged in the display pad portion and a signal line arranged in the pixel array layer 310, and a plurality of gate link lines connected with a plurality of gate pad electrodes arranged in the display pad portion and the gate driving circuit.

The panel driving circuit 900 may be packaged in the second glass substrate 120 to supply a signal for displaying an image to the pixel array layer 310. The panel driving circuit 900 according to one example may include a flexible circuit film 930 and a driving integrated circuit 910. The flexible circuit film 930 may be attached to one side of the first glass substrate 120 through a film attachment process.

The driving integrated circuit 910 is packaged in the flexible circuit film 930 by a chip bonding process or a surface packaging process. The driving integrated circuit 910 generates a data signal and a gate control signal based on a timing synchronizing signal and image data supplied from an external display driving system, supplies the data signal to the data line of each pixel and supplies the gate control signal to the gate driving circuit.

Optionally, the driving integrated circuit 910 may electrically be connected to the pad portion by being packaged in the second glass substrate 120 without being packaged in the flexible circuit film 930, and may electrically be connected to each of the pixel driving signal line and the gate driving circuit. In this case, the flexible circuit film 930 serves to relay signal transmission between the pad portion and the display driving system.

The first mask member 410 may be provided on the first rear surface 110c of the first glass substrate 110, and the second mask member 420 may be provided on the second rear surface 120c of the second glass substrate 120.

In this case, the first mask member 410 and the second mask member 420 may have etching resistance to the etching solution of the glass substrate 120, and may serve to etch the first etching surface 110b and the second etching surface 120b of the first glass substrate 110 and the second glass substrate 120 and prevent the first rear surface 110c and the second rear surface 120c of the first glass substrate 110 and the second glass substrate 120 from being etched.

Also, since the first mask member 410 and the second mask member 420 are respectively arranged on the first rear surface 110c and the second rear surface 120c of the first glass substrate 110 and the second glass substrate 120, scattering and damage caused by etching of the first glass substrate 110 and the second glass substrate 120 may be prevented from occurring.

According to one example, the first mask member 410 and the second mask member 420 may include a polymer material have etching resistance to the etching solution of the first glass substrate 110 and the second glass substrate 120. The polymer material having resistance to the etching solution of the first glass substrate and the second glass substrate may include a hydrocarbon polymer of 1000 g/mol or more.

The polymer material having resistance to the etching solution of the first glass substrate 110 and the second glass substrate 120 may include at least one of polyethylene, polypropylene, polystyrene, polyvinyl chloride, ethylene vinyl acetate, polycarbonate, and polyethylene terephthalate.

Polyethylene may have the following chemical structural formula (1).

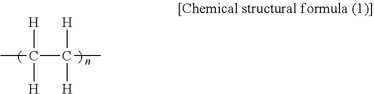

Polypropylene may have the following chemical structural formula (2).

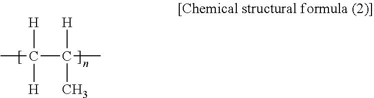

Polystyrene may have the following chemical structural formula (3).

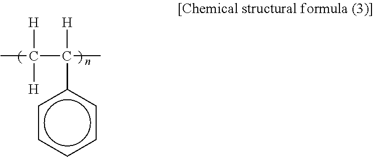

Polyvinyl chloride may have the following chemical structural formula (4).

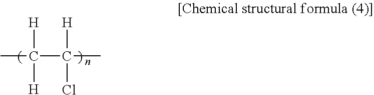

Ethylene vinyl acetate may have the following chemical structural formula (5).

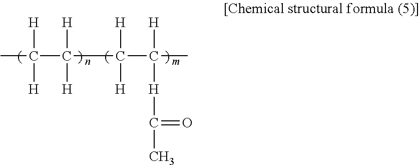

Polycarbonate may have the following chemical structural formula (6).

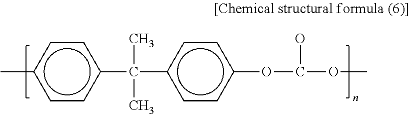

Polyethylene terephthalate may have the following chemical structural formula (7).

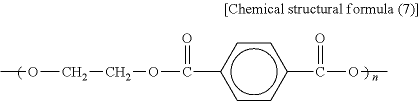

According to one example, the first mask member 410 and the second mask member 420 may respectively be arranged on the first rear surface 110c of the first glass substrate 110 and the second rear surface 120c of the second glass substrate 120.

According to one example, the first mask member 410 and the second mask member 420 may be set to a thickness of 10 μm to 400 μm.

According to another example, the first mask member 410 and the second mask member 420 may be set to a thickness of 10 μm to 100 μm. If the first mask member 410 and the second mask member 420 are set to a thickness of 10 μm to 100 μm, the thickness may be a thickness corresponding to the case that the first mask member 410 and the second mask member 420 include only the aforementioned acid-resistance polymer.

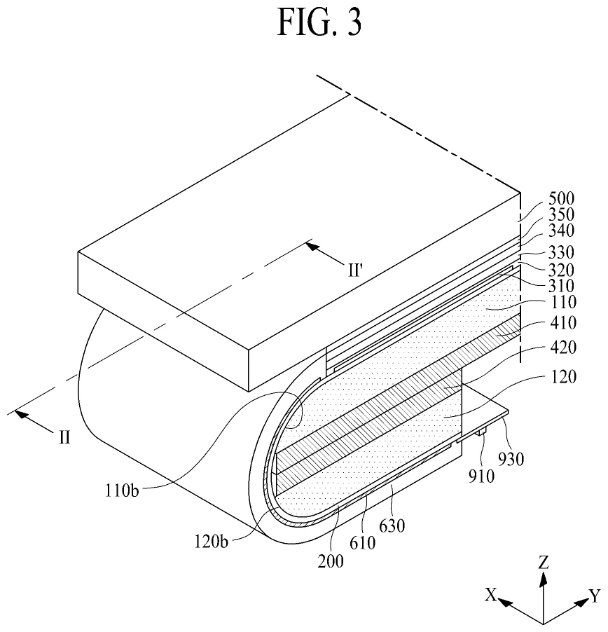

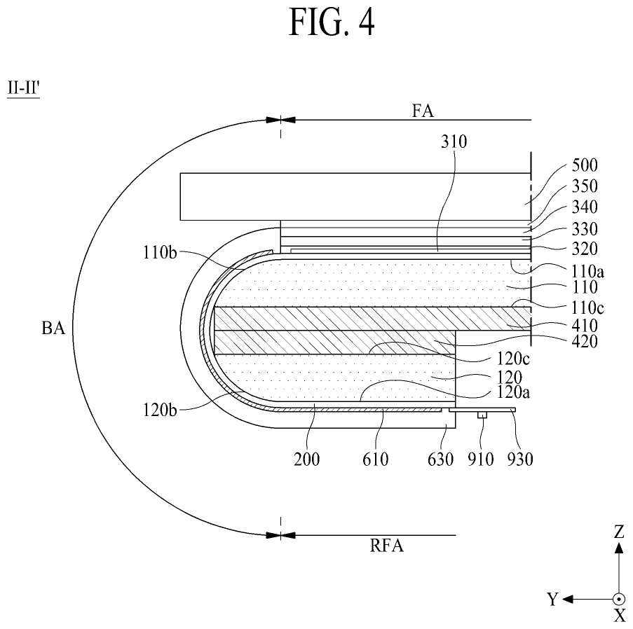

FIG. 3 is a perspective view illustrating a display apparatus according to one embodiment of the present disclosure, and FIG. 4 is a cross-sectional view taken along line II-IF of FIG. 3.

The display apparatus according to one embodiment of the present disclosure may further comprise an adhesive layer 350 arranged on the touch sensor layer 330 and a cover glass 500 provided on the adhesive layer 350.

The adhesive layer 350 may include a pressure-sensitive adhesive, a foam-type adhesive, a liquid adhesive, a light-cured adhesive or another suitable adhesive material. In some embodiments, the adhesive layer 350 may be formed of a compressive material or include the compressive material and therefore may serve as a buffer member for a portion adhered by the adhesive layer 350. For example, the material of the adhesive layer 350 may be compressable. The adhesive layer 350 may be formed in a multi-layered structure that includes a buffer layer arranged between upper and lower layers of the adhesive material layer.

The cover glass 500 may be arranged to cover a front surface of the display apparatus and the bending area BA, and may serve to protect the display apparatus from external impact. The cover glass 500 according to one example may be made of a transparent material, a glass material or a reinforcing glass material.

As shown in FIGS. 3 and 4, the second glass substrate 120 may be bent toward an inner side of the display apparatus at 180°, and may be bent such that the second rear surface 120c of the second glass substrate 120 faces the first rear surface 110c of the first glass substrate 110 and the first mask member 410 is in contact with the second mask member 420. Also, the adhesive member for fixing the first mask member 410 to the second mask member 420 may further be arranged between the first mask member 410 and the second mask member 420.

As the flexible substrate 200 is arranged to be bent on the first etching surface 110b on the first glass substrate 110 and the second etching surface 120b on the second glass substrate 120 formed by a glass etching process in a curved shape, the flexible display apparatus according to one embodiment of the present disclosure may have a minimized bezel area. In more detail, as the first rear surface 110c of the first glass substrate 110 and the second rear surface 120c of the second glass substrate 120 are not arranged on the same line unlike the conventional display apparatus, the display apparatus has a bending structure with the second rear surface 120c of the second glass substrate 120 facing the first rear surface 110c of the first glass substrate 110, whereby the display apparatus in which the non-display area NDA is minimized may be provided.

The micro coating layer 630 may serve to protect a line by forming a resin in a bending position at a thin thickness because a crack may occur due to a tensile force acting on the link line portion 610 arranged on the flexible substrate 200 during bending. The micro coating layer 630 may be made of an acryl based material such as acrylate polymer.

The first etching surface 110b of the first glass substrate 110 and the second etching surface 120b of the second glass substrate 120 according to one embodiment of the present disclosure may be formed by a glass etching process based on over etch condition. In this case, the over etch condition may be defined by a glass etching process performed for a reference etching time or more, which is set to etch a glass of a certain thickness.

The first etching surface 110b of the first glass substrate 110 and the second etching surface 120b of the second glass substrate 120 may be formed in such a manner that a mask pattern is formed on a rear surface of a glass substrate (not shown) overlapped with the other areas FA and RFA except the bending area BA and then an area of the glass substrate overlapped with the bending area BA is etched in an oblique shape by the glass etching process using the mask pattern as a mask based on the over etch condition. In this case, the glass substrate (not shown) means a glass substrate before the first glass substrate 110 and the second glass substrate 120 are detached from each other by the glass etching process.

The first etching surface 110b of the first glass substrate 110 and the second etching surface 120b of the second glass substrate 120 may be formed as inclined surfaces having a convex curved shape. In this case, sectional areas of the first etching surface 110b of the first glass substrate 110 and the second etching surface 120b of the second glass substrate 120 may be increased as these etching surfaces become far away from the first flat surface 110a and the second flat surface 120a. For example, the sectional areas of the first etching surface 110b of the first glass substrate 110 and the second etching surface 120b of the second glass substrate 120 may be defined by a size of a horizontal cutting surface cut based on a horizontal surface parallel with the first flat surface 110a and the second flat surface 120a. The first etching surface 110b and the second etching surface 120b may be designated to have an inverse tapered shape.

FIGS. 5A to 5G illustrate a manufacturing method of a display apparatus according to one embodiment of the present disclosure.

First of all, as shown in FIG. 5A, the flexible substrate 200 is formed on the glass substrate 100, and then the pixel array layer 310, the overcoat layer 320 and the touch sensor layer 330 are sequentially formed on an upper surface corresponding to the display area DA of the glass substrate 100. Afterward, an additional mask member 490 is formed above the touch sensor layer 330 to prevent the pixel array layer 310, the overcoat layer 320 and the touch sensor layer 330 from being damaged by the etching solution of the glass substrate when a glass substrate thinning process is performed. At this time, the glass substrate 100 may have a thickness of a first thickness t1.

Next, as shown in FIG. 5B, a thinning process of the glass substrate 100 is performed. After the thinning process is performed, the thickness of the glass substrate 100 may be a second thickness t2 ranging from 0.05 mm to 0.2 mm. However, the second thickness t2 of the glass substrate 100 is not limited to this range, and may be used without limitation if it is applied to the display apparatus in the art.

Next, as shown in FIGS. 5C and 5D, a mask member 400 is formed on a lower surface of the glass substrate 100 and then removed as much as a first width W1. At this time, as a process of removing the mask member 400, a laser cutting or wheel cutting process may be used. In this case, the mask member 400 may be a mask member before the first mask member 410 and the second mask member 420 described in FIGS. 1 and 2 are patterned or cut.

Next, as shown in FIG. 5E, the glass substrate 100 is etched using the cut mask member 400 as a mask pattern, whereby the glass substrate 100 is divided into the first glass substrate 110 and the second glass substrate 120, and the first etching surface 110b of the first glass substrate 110 and the second etching surface 120b of the second glass substrate 120, which are overlapped with the bending area BA of the display apparatus, are formed. In this case, the glass etching process may be performed by a wet etching process not a dry etching process.

The process of etching the glass substrate 100 may be performed by an over etch condition to form the first etching surface 110b of the first glass substrate 110 and the second etching surface 120b of the second glass substrate 120. In this case, the over etch condition may be defined by a glass etching process performed by exceeding a reference etching time that may etch the glass substrate of a certain thickness. If the glass etching process based on the over etch condition is performed, over etching occurs from the rear surfaces 110c and 120c of the first glass substrate 110 and the second glass substrate 120 to the flat surfaces 110a and 120a of the first glass substrate 110 and the second glass substrate 120 adjacent to the rear surface of the flexible substrate 200 in accordance with the passage of the etching time, whereby undercut UC may occur between the rear surface of the flexible substrate 200 and the flat surfaces 110a and 120a of the first glass substrate 110 and the second glass substrate 120 and as a result the first etching surface 110b of the first glass substrate 110 and the second etching surface 120b of the second glass substrate 120 may have an inverse tapered shape. In this case, undercut UC may be formed as the first glass substrate 110 and the second glass substrate 120 adjacent to the flexible substrate 200 are partially over etched in accordance with the etching process time performed to exceed the reference etching time.

In this case, the first glass substrate 110 may be defined by a first end E1 and a second end E2. The first end E1 may be defined by a boundary between the first flat surface 110a and the first etching surface 110b, and the second end E2 may be defined by a boundary between the first etching surface 110b and the first rear surface 110c. Also, a third end E3 and a fourth end E4 of the second glass substrate 120 may be defined as follows. The third end E3 may be defined by a boundary between the second flat surface 120a and the second etching surface 120b, and the fourth end E4 may be defined by a boundary between the second etching surface 120b and the second rear surface 120c.

A second width W3 and a third width W3 of the first glass substrate 110 may be defined with reference to the first end E1, the second end E2 of the first glass substrate 110, and the third end E3 and the fourth end E4 of the second glass substrate 120. The second width W2 may be defined as a width between the first end E1 and the third end E3, and the third width W3 may be defined as a width between the second end E2 and the fourth end D4.

According to one embodiment of the present disclosure, the second width W2 may be controlled at the same level as the first width W1. As described in FIG. 5B, since the etching process of the glass substrate 100 is performed after the thinning process of the glass substrate 100 is performed, the glass substrate 100 may be etched to correspond to the mask pattern defined by the first mask member 410 and the second mask member 420, and control of the etched area of the glass substrate 100 may be improved.

For example, if the etching process of the glass substrate is performed after the thickness of the glass substrate 100 is prepared as the first thickness t1 thicker than the second thickness, the second width W2 may be wider than the first width W1, and if the glass substrate 100 is etched to exceed the set area, a problem may occur in reliability of the display apparatus.

In this case, referring to the second width W2 and the third width W3 of FIG. 5D, the undercut and inverse tapered shape of the first etching surface 110b of the first glass substrate 100 and the second etching surface 120b of the second substrate 120 may mean that the first etching surface 110b of the first glass substrate 100 and the second etching surface 120b of the second substrate 120 are formed such that the third width W3 is greater than the second width W2.

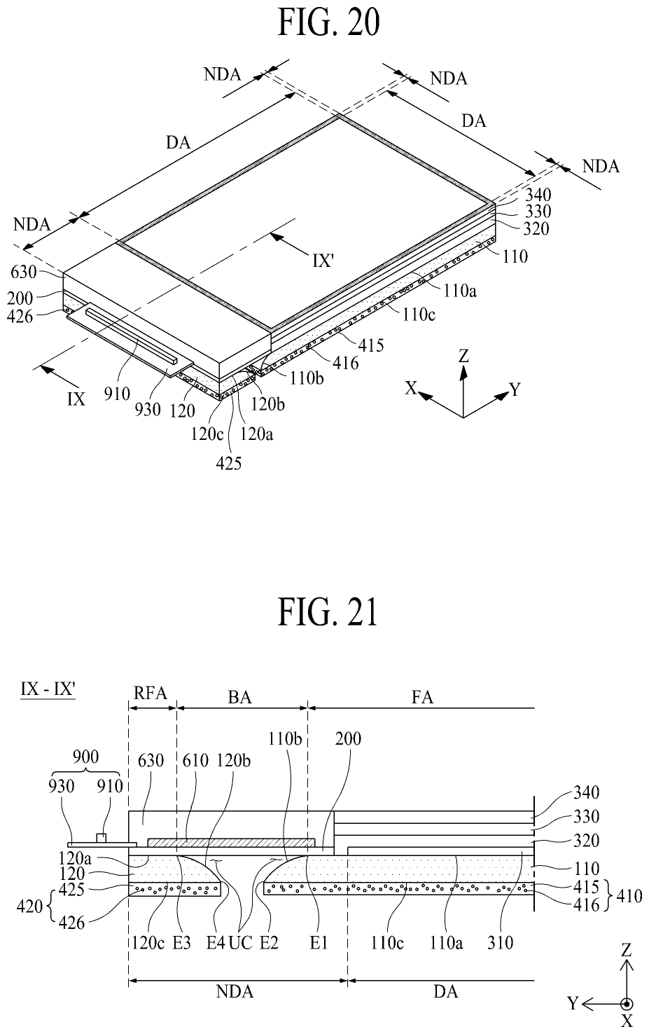

Also, the undercut and inverse tapered shape of the first etching surface 110b of the first glass substrate 100 and the second etching surface 120b of the second glass substrate 120 may be prepared in various shapes based on the second width W2 and the third width w3 if the third width W2 is set to be greater than the second width W2. However, the third width W3 may be set so as not to exceed the flexible substrate in case of the display apparatus of FIGS. 16 and 20, which will be described later. Also, the third width W3 may preferably be set to non-overlap the flat area FA or the rear flat area RFA except the bending area BA.

At this time, a distance between the first rear surface 110c and the second rear surface 120c of the first glass substrate 110 and the second glass substrate 120 may be set to the second width s2.

Next, as shown in FIGS. 5F and 5G, the additional mask member 490 provided on the touch sensor layer 330 may be removed and then the adhesive layer 350 and the cover glass 500 may be formed.

FIGS. 6A to 6C are another example of a sectional view taken along line II-II′ of FIG. 3. Since the display apparatus shown in FIGS. 6A to 6C is the same as the display apparatus shown in FIG. 4 except an adhesive member 800 arranged between the first mask member 410 and the second mask member 420 and shapes of the first etching surface 110b of the first glass substrate 110 and the second etching surface 120b of the second glass substrate 120, its repeated description will be omitted.

Referring to FIG. 6A, the display apparatus according to one embodiment of the present disclosure may further comprise an adhesive member 800 arranged between the first mask member 410 and the second mask member 420. The adhesive member 800 may be, but not limited to, an optically clear adhesive (OCA), an optically clear resin (OCR), a pressure sensitive adhesive (PSA), a double side adhesive, or a double side tape.

Referring to FIG. 6B, at least a portion of the first etching surface 110b of the first glass substrate 110 and the second etching surface 120b of the second glass substrate 120 has an inverse tapered shape or undercut UC structure, and may include a vertical etching surface substantially parallel with a third direction Z. A first direction X and a second direction Y may indicate random directions orthogonal to each other on a plane, and in the present disclosure, a direction parallel with a short side of the display apparatus based on FIG. 1 is defined as the first direction X, and a direction orthogonal to the first direction is defined as the second direction Y. Next, the third direction Z is defined as a direction vertical to a plane provided by the first direction X and the second direction Y.

Therefore, the display apparatus shown in FIG. 6B may be provided such that a portion of the first etching surface 110b of the first glass substrate 110 and the second etching surface 120b of the second glass substrate 120 is in contact with the flexible substrate 200 and at least a portion of the first etching surface 110b of the first glass substrate 110 and the second etching surface 120b of the second glass substrate 120 is non-overlapped with the flexible substrate 200. Therefore, in the display apparatus of FIG. 6B, the flexible substrate 200, the link line portion 610 and the micro coating layer 630, which are overlapped with the bending area BA, may be spaced apart from one another at a predetermined distance to have a degree of freedom.

As shown in a sectional view of FIG. 6C, if at least a portion of the first etching surface 110b of the first glass substrate 110 and the second etching surface 120b of the second glass substrate 120 is not in contact with the flexible substrate 200, an elastic member 700 may additionally be provided below the flexible substrate 200. Therefore, as the elastic member 700 is additionally provided below the flexible substrate 200, the elastic member 700 may support the flexible substrate 200 overlapped with the bending area BA. In this case, the elastic member 700 may be used as the term such as a moisture proofing member, a filling member or an elongation member. The elastic member 700 may be arranged on the rear surface of the flexible substrate 200 overlapped with the bending area BA. Also, although FIG. 6C shows that the elastic member 700 is not deposited between the first and second etching surfaces 110b and 120b and the flexible substrate 200, the elastic member 700 may be provided to fill a fine gap between the first and second etching surfaces 110b and 120b and the flexible substrate 200.

FIGS. 7A to 7D are other example of a sectional view taken along line II-IF of FIG. 3.

Referring to FIGS. 7A to 7C, the first etching surface 110b of the first glass substrate 110 and the second etching surface 120b of the second glass substrate 120 may have a forward tapered shape and a curved surface, and may be provided not to be in contact with the flexible substrate 200.

The first etching surface 110b of the first glass substrate 110 and the second etching surface 120b of the second glass substrate 120 according to one embodiment of the present disclosure may be formed by a glass etching process based on a soft etch condition. In this case, the soft etch condition may be defined by a glass etching process performed for a time less than a reference etching time set to etch a glass of a certain thickness.

The first etching surface 110b of the first glass substrate 110 and the second etching surface 120b of the second glass substrate 120 may be formed in such a manner that a mask pattern is formed on a rear surface of a glass substrate (not shown) overlapped with the other areas FA and RFA except the bending area BA and then an area of the glass substrate overlapped with the bending area BA is etched in an oblique shape by the glass etching process using the mask pattern as a mask based on the soft etch condition. In this case, the glass substrate (not shown) means a glass substrate before the first glass substrate 110 and the second glass substrate 120 are detached from each other by the glass etching process.

The first etching surface 110b of the first glass substrate 110 and the second etching surface 120b of the second glass substrate 120 may be formed as inclined surfaces having a convex curved shape or linear shape. In this case, sectional areas of the first etching surface 110b of the first glass substrate 110 and the second etching surface 120b of the second glass substrate 120 may be reduced as these etching surfaces become far away from the first flat surface 110a and the second flat surface 120a. For example, the sectional areas of the first etching surface 110b of the first glass substrate 110 and the second etching surface 120b of the second glass substrate 120 may be defined by a size of a horizontal cutting surface cut based on a horizontal surface parallel with the first flat surface 110a and the second flat surface 120a. The first etching surface 110b and the second etching surface 120b may be designated to have a forward tapered shape.

As shown in FIGS. 7A to 7C, the first etching surface 110b of the first glass substrate 110 and the second etching surface 120b of the second glass substrate 120 according to one embodiment of the present disclosure may have a forward tapered structure, and therefore may not be in contact with the flexible substrate 200. Also, as shown in FIG. 7C, the display apparatus may further comprise an elastic member 700 provided below the flexible substrate 200.

Referring to FIG. 7D, the first etching surface 110b of the first glass substrate 110 and the second etching surface 120b of the second glass substrate 120 may have rounded-edge ends or stumpy ends which are not sharp. The structure of the first etching surface 110b of the first glass substrate 110 and the second etching surface 120b of the second glass substrate 120 having rounded-edge ends or stumpy ends may be a structure that a stress is slowly dispersed when supporting the flexible substrate 200, whereby reliability of the display apparatus may be improved. Also, although FIG. 7d shows that the elastic member 700 is not deposited between the first and second etching surfaces 110b and 120b and the flexible substrate 200, the elastic member 700 may be provided to fill a fine gap between the first and second etching surfaces 110b and 120b and the flexible substrate 200.

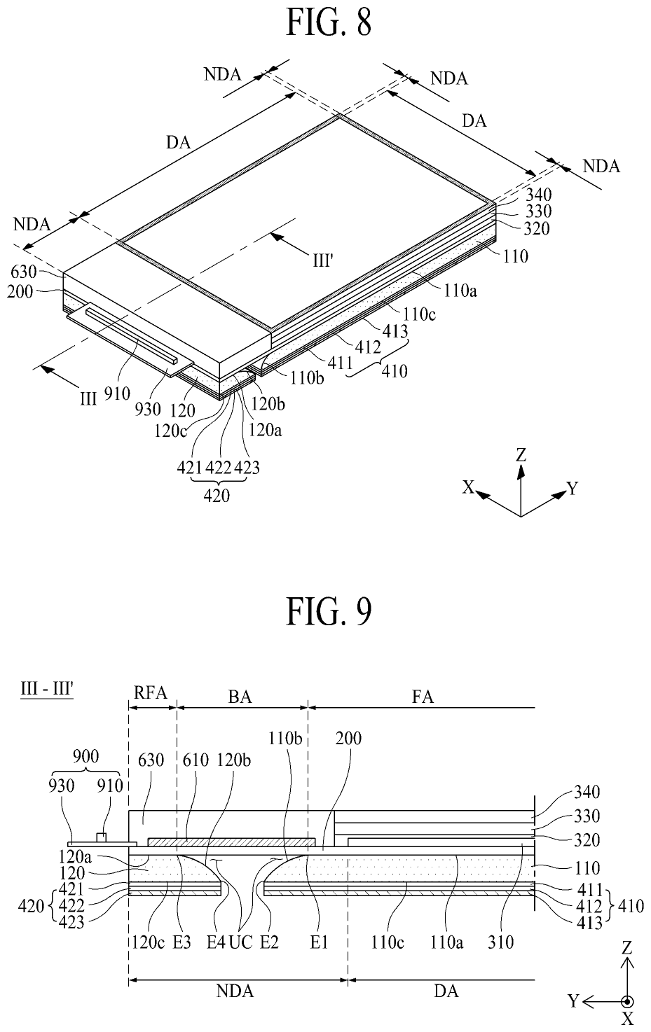

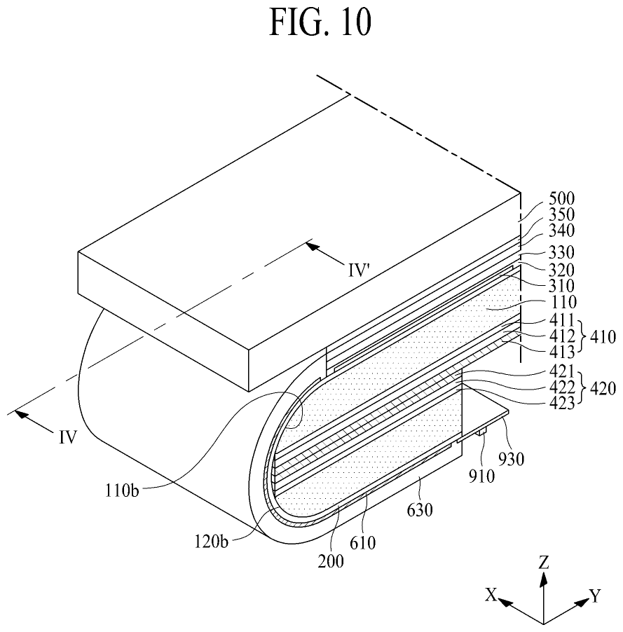

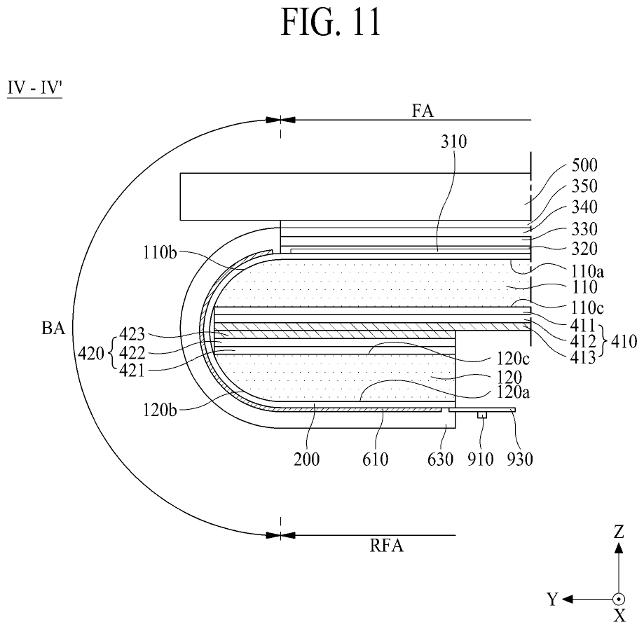

FIG. 8 is a perspective view illustrating a display apparatus according to one embodiment of the present disclosure, FIG. 9 is a cross-sectional view taken along line III-III′ of FIG. 8, FIG. 10 is a perspective view illustrating a display apparatus according to one embodiment of the present disclosure, and FIG. 11 is a cross-sectional view taken along line IV-IV′ of FIG. 10. Since the display apparatus shown in FIGS. 8 to 11 is the same as the display apparatus shown in FIGS. 1 to 4 except that the first mask member 410 and the second mask member 420 are modified, its repeated description will be omitted.

Referring to FIGS. 8 to 11, the first mask member 410 may include a first mask member adhesive layer 411, a first mask member metal layer 412, and a first mask member anti-etching layer 413, and the second mask member 420 may include a second mask member adhesive layer 421, a second mask member metal layer 422, and a second mask member anti-etching layer 423.

The first mask member anti-etching layer 413 and the second mask member anti-etching layer 423 may include a polymer material have resistance to the etching solution of the aforementioned glass substrate. Therefore, the first mask member anti-etching layer 413 and the second mask member anti-etching layer 423 may include a polymer material have resistance to the etching solution of the first glass substrate 110 and the second glass substrate 120. A weight average molecular weight of the polymer material having resistance to the etching solution of the first glass substrate 110 and the second glass substrate 120 may include a hydrocarbon polymer having a weight average molecular weight of 1000 g/mol or more. Also, the first mask member anti-etching layer 413 and the second mask member anti-etching layer 423 may consist of the same material as of as the first mask member 410 and the second mask member 420, as described in FIGS. 1 to 4.

The polymer material having resistance to the etching solution of the first glass substrate 110 and the second glass substrate 120 may include at least one of polyethylene, polypropylene, polystyrene, polyvinyl chloride, ethylene vinyl acetate, polycarbonate, and polyethylene terephthalate.

At this time, the first mask member anti-etching layer 413 and the second mask member anti-etching layer 423 may be set to a thickness of 10 μm to 100 μm.

If the first mask member anti-etching layer 413 and the second mask member anti-etching layer 423 are set to a thickness less than 10 μm, these mask member anti-etching layers may fail to perform a mask pattern function for the glass etching solution. Also, if the first mask member anti-etching layer 413 and the second mask member anti-etching layer 423 are set to a thickness of 100 μm or more, a problem may occur in that the display apparatus becomes thick.

The first mask member metal layer 412 and the second mask member metal layer 422 may include a metal material of high heat conductivity. Therefore, heat dispersion and heat emission effect of the display apparatus may be improved by the first mask member metal layer 412 and the second mask member metal layer 422.

The first mask member metal layer 412 and the second mask member metal layer 422 may be set to a thickness of 1 μm to 100 μm.

If the first mask member metal layer 412 and the second mask member metal layer 422 are set to a thickness less than 1 μm, heat dispersion and heat emission effect of the display apparatus may be deteriorated. If the first mask member metal layer 412 and the second mask member metal layer 422 are set to a thickness exceeding 100 μm, a problem may occur in that a weight of the display apparatus is increased.

The first mask member adhesive layer 411 and the second mask member adhesive layer 421 may serve to respectively attach the first mask member metal layer 412 and the second mask member metal layer 422 to the first glass substrate 110 and the second glass substrate 120, and may serve to absorb impact through a buffering action.

Each of the first mask member adhesive layer 411 and the second mask member adhesive layer 421 may be set to a thickness of 10 μm to 200 μm. If the first mask member adhesive layer 411 and the second mask member adhesive layer 421 are set to a thickness of 10 μm or less, adhesive characteristic and impact absorption characteristic may be deteriorated. If the first mask member adhesive layer 411 and the second mask member adhesive layer 421 are set to a thickness exceeding 200 μm, a problem may occur in that a thickness and a weight of the display apparatus are increased.

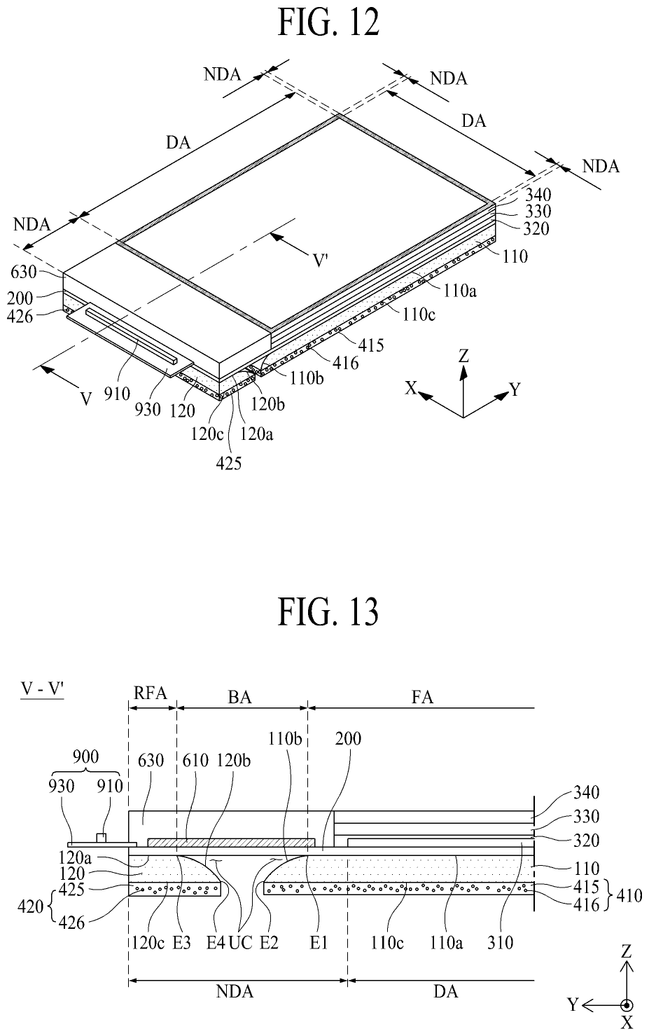

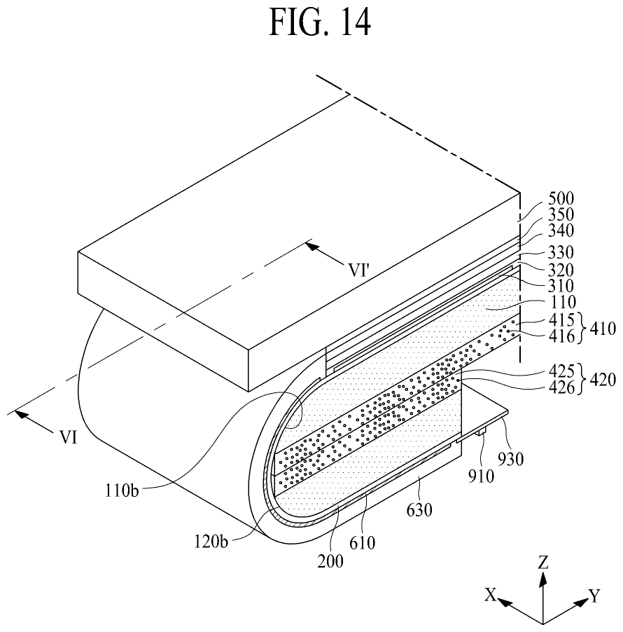

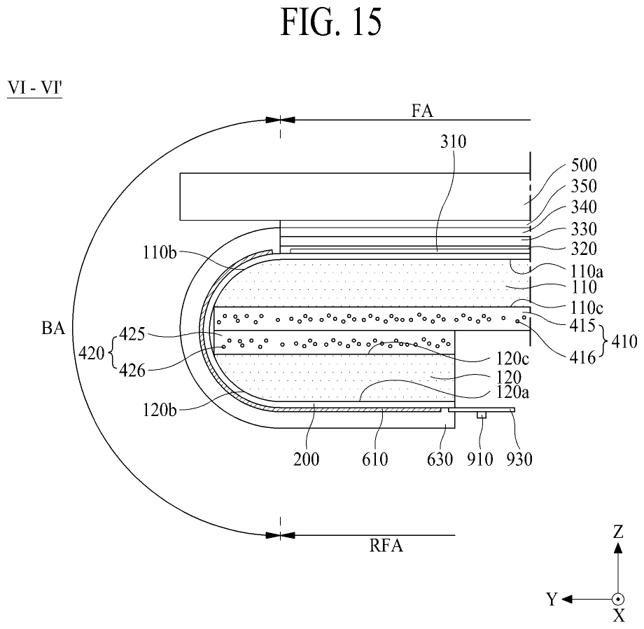

FIG. 12 is a perspective view illustrating a display apparatus according to one embodiment of the present disclosure, FIG. 13 is a cross-sectional view taken along line V-V′ of FIG. 12, FIG. 14 is a perspective view illustrating a display apparatus according to one embodiment of the present disclosure, and FIG. 15 is a cross-sectional view taken along line VI-VI′ of FIG. 13. Since the display apparatus shown in FIGS. 12 to 15 is the same as the display apparatus shown in FIGS. 1 to 4 except that the first mask member 410 and the second mask member 420 are modified, its repeated description will be omitted.

Referring to FIGS. 12 to 15, the first mask member 410 may include a first mask member resin layer 415 and a first mask member heat conductive particle 416, and the second mask member 420 may include a second mask member resin layer 425 and a second mask member heat conductive particle 426.

According to one example, each of the first mask member resin layer 415 and the second mask member resin layer 425 may include a material constituting a matrix of the first mask member 410 and the second mask member 420.

Also, the first mask member resin layer 415 and the second mask member resin layer 425 may include a photoresist resin. Therefore, the first mask member resin layer 415 and the second mask member resin layer 425 may be a material that may be patterned by a photolithography process.

Therefore, the first mask member 410 and the second mask member 420 may be formed through patterning after depositing the mask member 400 that includes the photoresist resin. In this case, the mask member 400 may mean a mask member before patterning is performed for the first mask member 410 and the second mask member 420 as shown in FIGS. 5A to 5C. Patterning of the mask member 400 may be performed by a photolithography process, which includes exposure, developing and hardening steps, using a mask pattern.

Also, the first mask member 410 and the second mask member 420 may respectively include a first mask member heat conductive particle 416 and a second mask member heat conductive particle 426. In this case, the heat conductive particle may be a metal particle or carbon particle having high heat conductive characteristic. Therefore, the first mask member 410 and the second mask member 420 that include the first mask member heat conductive particle 416 and the second mask member heat conductive particle 426 may improve heat dispersion and heat emission characteristic of the display apparatus.

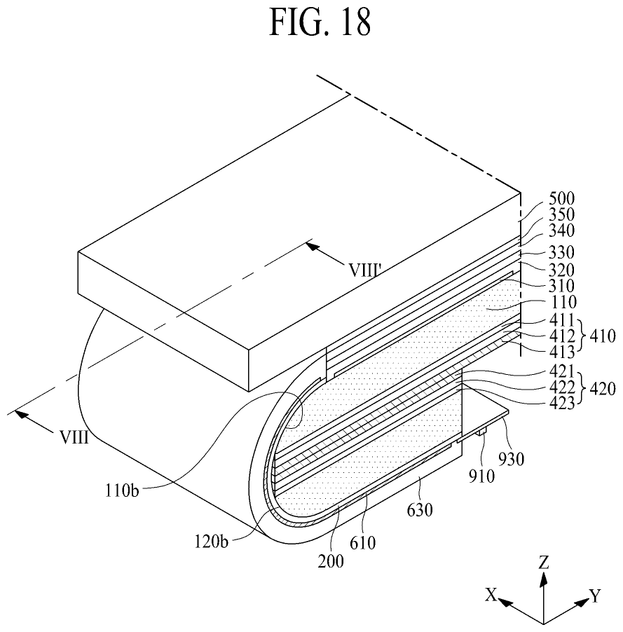

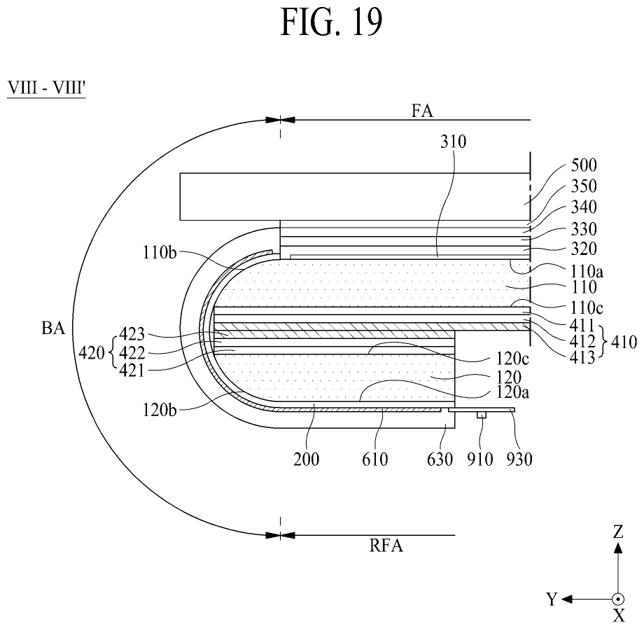

FIG. 16 is a perspective view illustrating a display apparatus according to one embodiment of the present disclosure, FIG. 17 is a cross-sectional view taken along line VII-VII′ of FIG. 16, FIG. 18 is a perspective view illustrating a display apparatus according to one embodiment of the present disclosure, and FIG. 19 is a cross-sectional view taken along line VIII-VIII′ of FIG. 18. Since the display apparatus shown in FIGS. 16 to 19 is the same as the display apparatus shown in FIGS. 8 to 11 except that the flexible substrate 200 is formed to overlap a portion of the non-display area NDA that includes the bending area BA, its repeated description will be omitted.

As shown in FIGS. 16 to 19, in the structure of the display apparatus according to one embodiment of the present disclosure, the pixel array layer 310 is formed to be directly in contact with first glass substrate 110. The flexible substrate 200 may not be arranged in an area corresponding to the display area DA or the flat area FA, and the pixel array layer 310 may directly be formed on the first glass substrate 110. Therefore, in the display apparatus according to one embodiment of the present disclosure, since the display portion of the display area DA does not require a sacrificial layer, an inter-layer dielectric layer or a buffer layer, which is arranged below the thin film transistor, as compared with the conventional display apparatus in which the flexible substrate 200 is arranged in the display portion of the display area DA, the process is simplified and the cost is reduced. Also, since the flexible substrate 200 is arranged in only the area overlapped with the bending area BA of the non-display area NDA, the manufacturing cost may be reduced.

Also, as the display apparatus according to one embodiment of the present disclosure provides a structure that the flexible substrate 200 is not arranged in the display area DA, luminance or residual image characteristics caused by the flexible substrate 200, which may occur in the display area DA, may be improved, whereby a defect rate may be reduced and yield may be improved.

According to one embodiment of the present disclosure, a thickness of the flexible substrate 200 may be set to 10 μm or less. If the thickness of the flexible substrate 200 exceeds 10 μm, a step difference may occur in a boundary portion of the display area DA and bending area BA or between the flat area FA and the bending area BA, and it is likely that disconnection of a link line portion 610 due to occurrence of stress caused by the step difference may occur. In this case, the step difference means a step difference occurring in the boundary portion between the display area DA and the bending area BA or between the flat area FA and the bending area BA as the flexible substrate 200 is partially formed to overlap the bending area BA.

Also, in the present disclosure, as the flexible substrate 200 is formed in only the bending area BA without being arranged in the first glass substrate 110, a laser release process for detaching the glass substrate from the flexible substrate 200 may be omitted. In the present disclosure, since the flexible display apparatus may be manufactured even without an expensive laser equipment, the manufacturing cost may be reduced, and a laser release related defect (particles or transfer according to surface roughness of the flexible substrate 200) is not generated. Since a sacrificial layer, an inter-layer dielectric layer or a buffer layer, which is required when the flexible substrate 200 is applied to the display area DA, may be omitted, the process may be simplified, and the manufacturing cost may be reduced.

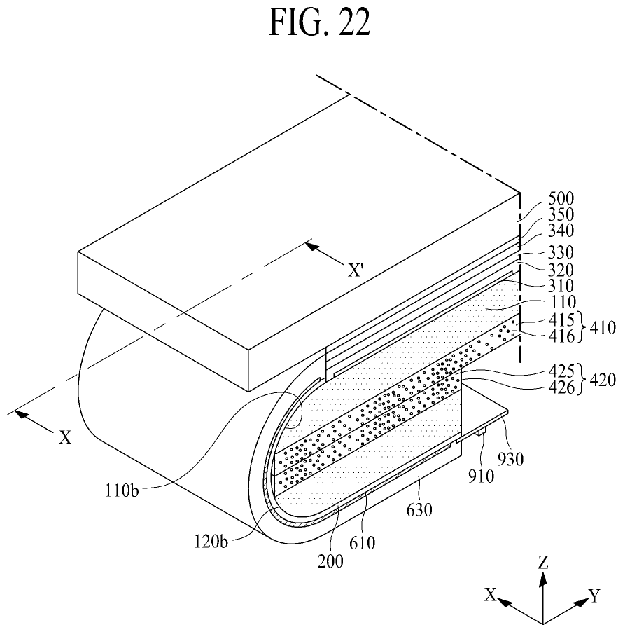

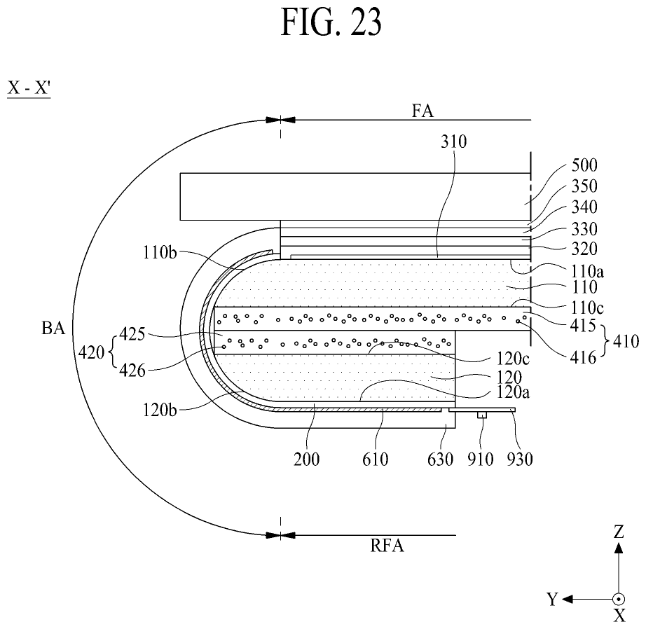

FIG. 20 is a perspective view illustrating a display apparatus according to one embodiment of the present disclosure, FIG. 21 is a cross-sectional view taken along line IX-IX′ of FIG. 20, FIG. 22 is a perspective view illustrating a display apparatus according to one embodiment of the present disclosure, and FIG. 23 is a cross-sectional view taken along line X-X′ of FIG. 22. Since the display apparatus shown in FIGS. 20 to 23 is the same as the display apparatus shown in FIGS. 12 to 15 except that the flexible substrate 200 is formed to overlap a portion of the non-display area NDA that includes the bending area BA, its repeated description will be omitted.

As shown in FIGS. 20 to 23, in the structure of the display apparatus according to one embodiment of the present disclosure, the pixel array layer 310 is formed to be directly in contact with first glass substrate 110. The flexible substrate 200 may not be arranged in an area corresponding to the display area DA or the flat area FA, and the pixel array layer 310 may directly be formed on the first glass substrate 110. Therefore, in the display apparatus according to one embodiment of the present disclosure, since the display portion of the display area DA does not require a sacrificial layer, an inter-layer dielectric layer or a buffer layer, which is arranged below the thin film transistor, as compared with the conventional display apparatus in which the flexible substrate 200 is arranged in the display portion of the display area DA, the process is simplified and the cost is reduced. Also, since the flexible substrate 200 is arranged in only the area overlapped with the bending area BA of the non-display area NDA, the manufacturing cost may be reduced.

Also, as the display apparatus according to one embodiment of the present disclosure provides a structure that the flexible substrate 200 is not arranged in the display area DA, luminance or residual image characteristics caused by the flexible substrate 200, which may occur in the display area DA, may be improved, whereby a defect rate may be reduced and yield may be improved.

According to one embodiment of the present disclosure, a thickness of the flexible substrate 200 may be set to 10 μm or less. If the thickness of the flexible substrate 200 exceeds 10 μm, a step difference may occur in a boundary portion of the display area DA and bending area BA or between the flat area FA and the bending area BA, and it is likely that disconnection of a link line portion 610 due to occurrence of stress caused by the step difference may occur. In this case, the step difference means a step difference occurring in the boundary portion between the display area DA and the bending area BA or between the flat area FA and the bending area BA as the flexible substrate 200 is partially formed to overlap the bending area BA.

Also, in the present disclosure, as the flexible substrate 200 is formed in only the bending area BA without being arranged in the first glass substrate 110, a laser release process for detaching the glass substrate from the flexible substrate 200 may be omitted. In the present disclosure, since the flexible display apparatus may be manufactured even without an expensive laser equipment, the manufacturing cost may be reduced, and a laser release related defect (particles or transfer according to surface roughness of the flexible substrate 200) is not generated. Since a sacrificial layer, an inter-layer dielectric layer or a buffer layer, which is required when the flexible substrate 200 is applied to the display area DA, may be omitted, the process may be simplified, and the manufacturing cost may be reduced.

The display apparatus according to one embodiment of the present disclosure may be described as follows.

The display apparatus according to one embodiment of the present disclosure relates to a display apparatus comprising a display area, a non-display area surrounding the display area, and a bending area formed in at least one side of the non-display area, and comprises a first glass substrate including a first flat surface and a first rear surface opposite to the first flat surface, the first flat surface being overlapped with the display area, a second glass substrate including a second flat surface and a second rear surface opposite to the second flat surface, the second flat surface being overlapped with the non-display area adjacent to the bending area, a first mask member provided on the first rear surface, and a second mask member provided on the second rear surface.

According to some embodiments of the present disclosure, the first mask member and the second mask member may include a polymer material having resistance to an etching solution of the first glass substrate and the second glass substrate.

According to some embodiments of the present disclosure, the polymer material may include a hydrocarbon polymer having a weight average molecular weight of 1000 g/mol or more.

According to some embodiments of the present disclosure, the mask member may include at least one of polyethylene, polypropylene, polystyrene, polyvinyl chloride, ethylene vinyl acetate, polycarbonate, and polyethylene terephthalate.

According to some embodiments of the present disclosure, the first mask member may include a first mask member metal layer arranged to adjacent to the first rear surface, and a first mask member anti-etching layer arranged below the first mask member metal layer.

According to some embodiments of the present disclosure, the first mask member anti-etching layer may include a polymer material having resistance to an etching solution of the first glass substrate and the second glass substrate.

According to some embodiments of the present disclosure, the first mask member may further include a first mask member adhesive layer arranged between the first glass substrate and the first mask member metal layer.

According to some embodiments of the present disclosure, the second mask member may include a second mask member metal layer arranged to adjacent to the second rear surface, and a second mask member anti-etching layer arranged below the second mask member metal layer.

According to some embodiments of the present disclosure, the second mask member may further include a second mask member adhesive layer arranged between the second glass substrate and the second mask member metal layer.

According to some embodiments of the present disclosure, the second mask member anti-etching layer may include a polymer material having resistance to an etching solution of the first glass substrate and the second glass substrate.

According to some embodiments of the present disclosure, the first mask member may include a first mask member resin layer constituting a matrix of the first mask member, and a first mask member heat conductive particle dispersed in the first mask member resin layer.

According to some embodiments of the present disclosure, the heat conductive particle may include at least one of a metal particle and a carbon particle.

According to some embodiments of the present disclosure, the first mask member resin layer may include a photoresist resin.

According to some embodiments of the present disclosure, the second mask member may include a second mask member resin layer constituting a matrix of the second mask member, and a second mask member heat conductive particle dispersed in the second mask member resin layer.

According to some embodiments of the present disclosure, the heat conductive particle may include at least one of a metal particle and a carbon particle.

According to some embodiments of the present disclosure, the second mask member resin layer may include a photoresist resin.

According to some embodiments of the present disclosure, the first glass substrate may include a first end arranged at one side of the first flat surface, a second end arranged at one side of the first rear surface, and a first etching surface connecting the first end with the second end.

According to some embodiments of the present disclosure, the second glass substrate may include a third end arranged at one side of the second flat surface, a fourth end arranged at one side of the second rear surface, and a second etching surface connecting the third end with the fourth end.

According to some embodiments of the present disclosure, the display apparatus may further comprise a flexible substrate overlapped with the bending area, wherein the flexible substrate may be overlapped with the first etching surface and the second etching surface.

According to some embodiments of the present disclosure, the flexible substrate may be provided on the first flat surface and the second flat surface.

According to some embodiments of the present disclosure, the flexible substrate may include at least one of polyimide, photo acryl, polyurethane and silicone based organic matter.

According to some embodiments of the present disclosure, the flexible substrate may have a thickness of 10 μm or less.

It will be apparent to those skilled in the art that the present disclosure described above is not limited by the above-described embodiments and the accompanying drawings and that various substitutions, modifications, and variations can be made in the present disclosure without departing from the spirit or scope of the disclosures. Consequently, the scope of the present disclosure is defined by the accompanying claims, and it is intended that all variations or modifications derived from the meaning, scope, and equivalent concept of the claims fall within the scope of the present disclosure.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus comprising a display area, a non-display area surrounding the display area, and a bending area formed in at least one side of the non-display area, the display apparatus comprising:
a first glass substrate including a first flat surface and a first rear surface opposite to the first flat surface, the first flat surface being overlapped with the display area;
a second glass substrate including a second flat surface and a second rear surface opposite to the second flat surface, the second flat surface being overlapped with the non-display area adjacent to the bending area;
a first mask member provided on the first rear surface; and
a second mask member provided on the second rear surface.

2. The display apparatus of claim 1, wherein the first mask member and the second mask member include a polymer material having resistance to an etching solution of the first glass substrate and the second glass substrate.

3. The display apparatus of claim 2, wherein the polymer material includes a hydrocarbon polymer having a weight average molecular weight of 1000 g/mol or more.

4. The display apparatus of claim 1, wherein the first mask member and the second mask member includes at least one of polyethylene, polypropylene, polystyrene, polyvinyl chloride, ethylene vinyl acetate, polycarbonate, and polyethylene terephthalate.

5. The display apparatus of claim 1, wherein the first mask member includes:
a first mask member metal layer arranged to adjacent to the first rear surface; and
a first mask member anti-etching layer arranged below the first mask member metal layer.

6. The display apparatus of claim 5, wherein the first mask member anti-etching layer includes a polymer material having resistance to an etching solution of the first glass substrate and the second glass substrate.

7. The display apparatus of claim 5, wherein the first mask member further includes a first mask member adhesive layer arranged between the first glass substrate and the first mask member metal layer.

8. The display apparatus of claim 1, wherein the second mask member includes:
a second mask member metal layer arranged to adjacent to the second rear surface; and
a second mask member anti-etching layer arranged below the second mask member metal layer.

9. The display apparatus of claim 8, wherein the second mask member further includes a second mask member adhesive layer arranged between the second glass substrate and the second mask member metal layer.

10. The display apparatus of claim 8, wherein the second mask member anti-etching layer includes a polymer material having resistance to an etching solution of the first glass substrate and the second glass substrate.

11. The display apparatus of claim 1, wherein the first mask member includes:
a first mask member resin layer constituting a matrix of the first mask member; and
a first mask member heat conductive particle dispersed in the first mask member resin layer.

12. The display apparatus of claim 11, wherein the first mask member heat conductive particle includes at least one of a metal particle and a carbon particle.

13. The display apparatus of claim 11, wherein the first mask member resin layer includes a photoresist resin.

14. The display apparatus of claim 1, wherein the second mask member includes:
a second mask member resin layer constituting a matrix of the second mask member; and
a second mask member heat conductive particle dispersed in the second mask member resin layer.

15. The display apparatus of claim 13, wherein the second mask member resin layer includes a photoresist resin.

16. The display apparatus of claim 1, wherein the first glass substrate includes:
a first end arranged at one side of the first flat surface;
a second end arranged at one side of the first rear surface; and
a first etching surface connecting the first end with the second end.

17. The display apparatus of claim 16, wherein the second glass substrate includes:
a third end arranged at one side of the second flat surface;
a fourth end arranged at one side of the second rear surface; and
a second etching surface connecting the third end with the fourth end.

18. The display apparatus of claim 17, further comprising a flexible substrate overlapped with the bending area, wherein the flexible substrate is overlapped with the first etching surface and the second etching surface.

19. The display apparatus of claim 18, wherein the flexible substrate is provided on the first flat surface and the second flat surface.

20. The display apparatus of claim 18, further comprising an elastic member arranged below the flexible substrate and arranged to overlap the bending area.
